(19) United States
(12) Patent Application Publication
(10) Pub. No.: US 2011/0041332 A1
(43) Pub. Date: Feb. 24, 2011

(54) CONNECTION COMPONENT PROVIDED WITH INSERTS COMPRISING COMPENSATING BLOCKS

(75) Inventors: Damien Saint-Patrice, Chabeuil (FR); Francois Marion, Saint-Martin Le Vinoux (FR)

Correspondence Address: MARJAMA MULDOON BLASIAK & SULLIVAN LLP, 250 SOUTH CLINTON STREET, SUITE 300, SYRACUSE, NY, 13202, US

(73) Assignee: Commissariat A L'Energie Atomique Et Aux Energies Alternatives

(21) Appl. No.: 12/918,641

(22) PCT Filed: Feb. 19, 2009
(86) PCT No.: PCT/FR09/00185

§ 371 Date: Nov. 10, 2010

(30) Foreign Application Priority Data
Feb. 22, 2008 (FR) 0851141

(51) Int. Cl. H05K 3/32

(52) U.S. Cl. 29/837

(57) ABSTRACT

The invention relates to a component comprising, on one face, a set of conductive inserts to be electrically connected to conductive buried regions of another component, said inserts resting on conductive blocks, advantageously produced from a deformable material and positioned at the surface of the component. The surface of the block, which is to come into contact with the insert, has at least one dimension larger than that of the buried region.

### CROSS REFERENCE TO RELATED APPLICATIONS

This application is a National Stage filing under 35 U.S.C. §371 of PCT Application No. PCT/FR2009/000185, filed on Feb. 19, 2009. This application also claims the benefit of French Application No. 0851141, filed Feb. 22, 2008. The entirety of both applications is incorporated herein by reference.

### FIELD OF THE INVENTION

The technical field to which the invention relates is that of microelectronics, and to be more specific that of the manufacture of micro- and nano-structures.

The invention relates to all sorts of devices comprising spikes or inserts that allow them to be interconnected for example with other electronic components with reduced pitches.

To be more precise, the invention proposes a particular form of inserts, and materials adapted to the implementation thereof. These make it possible, during the connection or hybridization process, to compensate for flatness defects related to the parallelism of the device or to the topography (topology) of the components.

### BACKGROUND OF THE INVENTION

In the field of connections that use the so-called “flip chip” technique, the current trend is towards reducing the “pitch”, in other words the distance between the interconnects connecting chip and substrate.

In said technique, a substrate carries all the contacts, in the form of protuberances or metal protuberances known as “bumps” which are located on a single face. The chip is flipped so that the protuberances are able to be soldered to appropriate conductors, positioned on this chip. However, conventional hybridization methods, such as the hard soldering of protuberances, the thermocompression of bumps, Anisotropic Conductive Films (ACF) or the use of conductive polymers show their limitations, in terms of reducing the pitch.

The document WO2006/054005 proposes an interconnection by insertion of a hard conductive spike into a ductile casing. This device, shown in FIG. 1, allows mechanical retention and electrical interconnection to be uncoupled. To do this, the electrical interconnection is made by inserting a spike 1, made out of a hard material, into a buried casing 2, made out of a ductile material.

This document proposes two different ways of retaining this structure mechanically: by molecular adhesion between the protuberances or by a layer of adhesive.

In fact, molecular adhesion between the protuberances is technologically difficult to implement, owing to the flatness requirement of the surfaces to be bonded. Indeed, since the substrate 3 and the chip 4, may be made out of different materials in the case of heterogeneous integration, they must be plane and have, as an additional constraint, different materials at the interface. By way of example and in relation to this document, the material constituting the substrate 3 is different from the material constituting the ductile casing 2. Moreover, the molecular adhesion temperature is generally high and incompatible with the integration of structures that have different thermal expansion coefficients.

The other alternative, namely adhesion by adhesive layer, is also difficult to implement, owing to the impossibility of integrating it after hybridization. Indeed, there is no space between the chip 4 and the substrate 3 to allow the adhesive to spread. Furthermore, the solution that comprises dispensing adhesive prior to hybridization cannot be entertained since said adhesive would be pushed out from the interface because of the pressure applied.

Additionally, this type of device cannot be used to compensate for parallelism defects during hybridization and the topology defects of the “wafer”. Indeed and as shown in FIG. 2, these defects create significant local pressures, damaging the component once and for all. Where a flatness defect is involved, non-contact regions may also be created.

### DISCLOSURE OF THE INVENTION

The proposed invention forms part of the search for a technical solution that makes it possible simultaneously to ensure electrical connection and mechanical retention and to compensate for topology defects due to the hybridization stage or to the “wafer” itself.

Thus and according to the invention, a component comprises, on one face, a set of conductive inserts to be electrically connected to conductive buried regions of another component.

Characteristically in accordance with the invention, the inserts rest on conductive blocks positioned at the surface of the component.

In the context of the invention, the components denote to advantage a chip or a substrate to be electrically and mechanically connected to another substrate. In practice, this may be a chip-to-wafer connection or a wafer-to-wafer connection.

Indeed a description had already been given of connecting said components using inserts, to advantage micro-inserts or micro-spikes, for insertion into ductile buried protuberances, present on the second component to be connected.

According to the invention, the connection device has an additional element, namely a block, also known as a base or step, arranged at the surface of the component, particularly the chip, and on which the insert rests.

The essential feature of this block is that it is conductive. This means that it is made out of a conductive material, subsequently referred to as M5, or out of an insulating material, such as a polymer, coated with a conductive layer.

Such a block is also defined by its height h′.

Advantageously, it has a surface larger than that of the support surface of the insert on this block.

To advantage, this conductive block has, on its contact surface with the insert, at least one dimension larger than that of the region located opposite the insert it carries. The depth of penetration of the insert into said protuberance is thus controlled by this block which is stopped, at least locally, at the surface of the other component. This stop block of height h′ thus allows a space to be provided between the two components, which is useful in particular for a layer of adhesive to be inserted therein.

According to a preferred feature, the conductive block is made from a deformable material (M5).

From this perspective and in a preferred way, the material (M5) of the conductive block has greater ductility than that of the material (M1) constituting the insert, or even than that of the material (M2) constituting the region into which the insert is inserted.

To fulfil this latter condition and by way of example, the insert is made out of gold (Au) and the block is composed of aluminium (Al) or indium (in), or it is made out of polymer coated with a film of Au.

As already stated, a structure such as this can be used to make good the flatness defects, related to the machine (FIG. 3), or to the wafer (FIG. 4) that are frequently encountered in the large-surface “flip-chip” interconnect field. Indeed because of the deformable nature of its constituent material, the height h′ of the block is capable of varying locally, and particularly of getting smaller when the stresses applied cause its compression.

According to the invention, it is therefore possible to dimension this block, as a function of the topology of the components to be connected.

The variation in maximum height, denoted Δh, is related to the maximum distance, denoted d, of the peripheral connections. Where a chip-to-wafer assembly is concerned, this distance is equal to the largest dimension of the interconnect region. Where a substrate-to-substrate assembly is concerned, this distance is equal to the largest distance between the peripheral connections of the chips on the plate edge.

The variation Δh between the peripheral connections separated by a distance d, to be compensated during hybridization, is thus expressed by the following formula:

Δh=tan(α)·d

wherein α represents the parallelism defect (FIG. 3)

For a given parallelism defect α, the variation in level Δh creating the stresses at a distance d is tabulated in the table below:

| Angle α | Δh (μm) for | Δh (μm) for |
|---|---|---|
| (mrad) | d = 2 cm | d = 20 cm |
| 0.001 | 0.02 | 0.20 |
| 0.01 | 0.20 | 2.00 |
| 0.03 | 0.60 | 6.00 |
| 0.05 | 1.00 | 10.00 |
| 0.1 | 2.00 | 20.00 |
| 0.2 | 4.00 | 40.00 |

In the context of the invention and in a preferred way, the height h′ of the block is dimensioned so that the plastic or resilient deformation of its constituent material M5 compensates for the flatness defects, embodied by the magnitude Δh.

Thus, if a deformation of less than Y % of the height of the block h′ is required, the thickness thereof (h′), in the case of a parallelism defect, is expressed by the following formula:

$${h}^{′} \geq \frac{tan ( α ) \cdot d}{Y / 100}$$

In the case of a defect related to the flatness of the wafer Δh (FIG. 4), the height h′ of the block, expressed as a function of the required deformation of Y %, is expressed by the formula:

$${h}^{′} \geq \frac{Y}{100} \cdot Δ h$$

The present invention relates therefore to a method for connection between two components, and in particular a chip and a substrate, the first component being provided with inserts resting on a block, as described below, and the second component being provided with buried conductive ductile regions arranged opposite these inserts.

It is therefore a matter of inserting the inserts into these regions until the block of the inserts is stopped, at least locally, at the surface of these regions that also corresponds to the surface of the second component.

Owing to the deformable nature of this block, it is possible to connect the two components in a parallel way, even in the event of a parallelism defect in the hybridization or of a non-constant thickness of the wafer.

According to the invention and as already stated, the conductive block is made out of a deformable material (M5), that has greater ductility than that of the material (M1) constituting the insert and than that of the material (M2) constituting the region. Furthermore it has a properly defined height h′:

Where a parallelism defect in the hybridization is involved, the height h′ of the block is defined as follows:

$${h}^{′} \geq \frac{tan ( α ) \cdot d}{Y / 100}$$

wherein:
α represents the parallelism defect;
d represents the maximum distance between two inserts (1); and
Y represents the deformation of the block (5) supporting the insert (1).

Where the thickness of the component is non-constant, the height h′ of the block is defined as follows:

$${h}^{′} \geq \frac{Y}{100} \cdot Δ h$$

wherein:
Δh represents the variation in maximum height between two interconnect elements (5, 1); and
Y represents the deformation of the block (5) supporting the insert (1).

It should be noted that this does not have to apply only to two juxtaposed inserts. In fact, Δh may therefore represent the variation in height between any two interconnect elements.

As already stated, the mechanical retention of this connection may be obtained by means of adhesive introduced into the space provided by the blocks of the inserts, at the interface of the two components.

Block dimensioning can also be used to anticipate the volume of adhesive to be introduced in order to ensure good retention. Particularly in the particular case of a chip-on-substrate hybridization, the volume of adhesive is as follows:

Vadhesive=1.1*(pitch²−L*l)*h′*N

where
pitch denotes the repetitive pitch between two elementary patterns;
N denotes the number of interconnect elements (element=insert+block);
h′ denotes the height of the inventive block;
L denotes the width of the inventive block; and
l denotes the length of the inventive block.

In this formula, the factor 1.1 allows the minimum volume for deposition to be overvalued by 10% in order to obtain a homogeneous bonding over the whole chip.

The adhesive may be dispensed by local deposition in the centre of the chip or by centrifugation in order to deposit a controlled height.

The present invention thus allows the inadequacies of the prior art to be resolved, namely the irreversible deterioration of the interconnect and of the component itself if the insert is not positioned over a deformable material, said deterioration being caused by the very significant local stresses related to parallelism defects at the insertion stage (cf. FIG. 2) or flatness defects.

As already stated, the present invention can be used in a great number of ways, particularly for the “flip chip” type interconnection of heterogeneous materials, for example for large-scale infrared imaging devices.

### BRIEF DESCRIPTION OF THE FIGURES

The way in which the invention may be implemented and the resulting advantages will become clearer from the following embodiment example, given for information purposes and non-restrictively, supported by the appended figures wherein:

FIG. 1 shows a substrate-to-chip connection system according to the prior art.

FIG. 2 shows the stresses exerted on a prior art device, in the event of there being a parallelism defect.

FIG. 3 is a diagram of the inventive structure allowing long-distance parallelism defects to be made good.

FIG. 4 is a diagram of the inventive structure allowing wafer topology-related flatness defects to be made good.

FIG. 5 is a diagram of the method for manufacturing an inventive device.

FIG. 6 shows the deformation of the inventive structure making good parallelism defects and allowing the integration of an adhesive film.

FIG. 7 shows the deformation of the inventive structure making good wafer-related flatness defects and allowing the integration of an adhesive film.

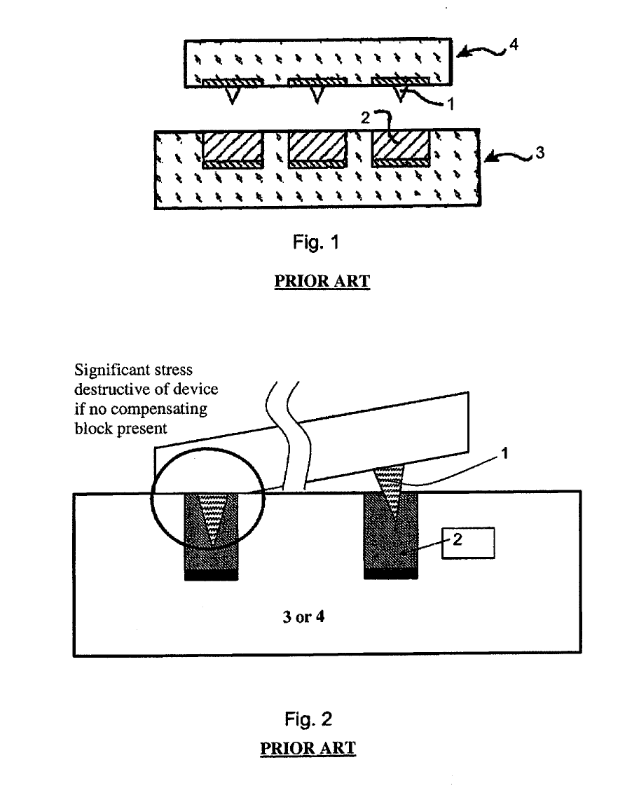

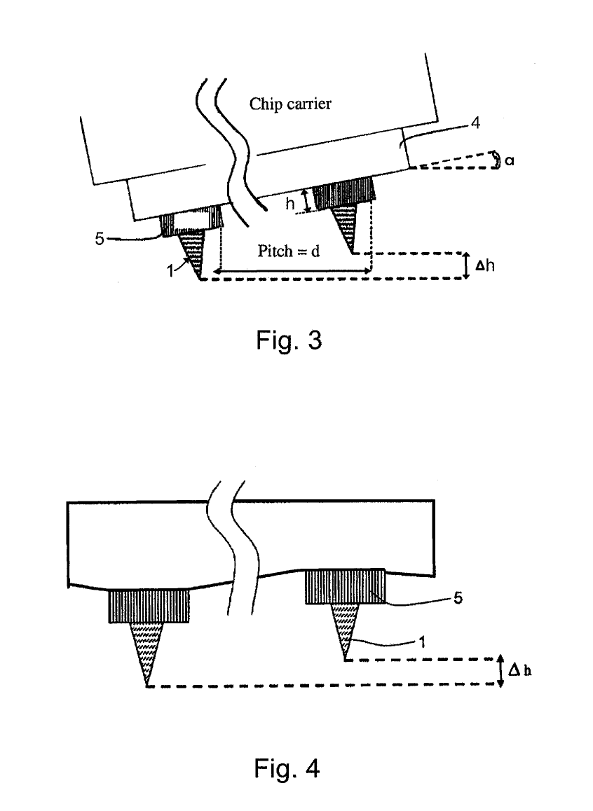

### DETAILED DESCRIPTION OF THE INVENTION

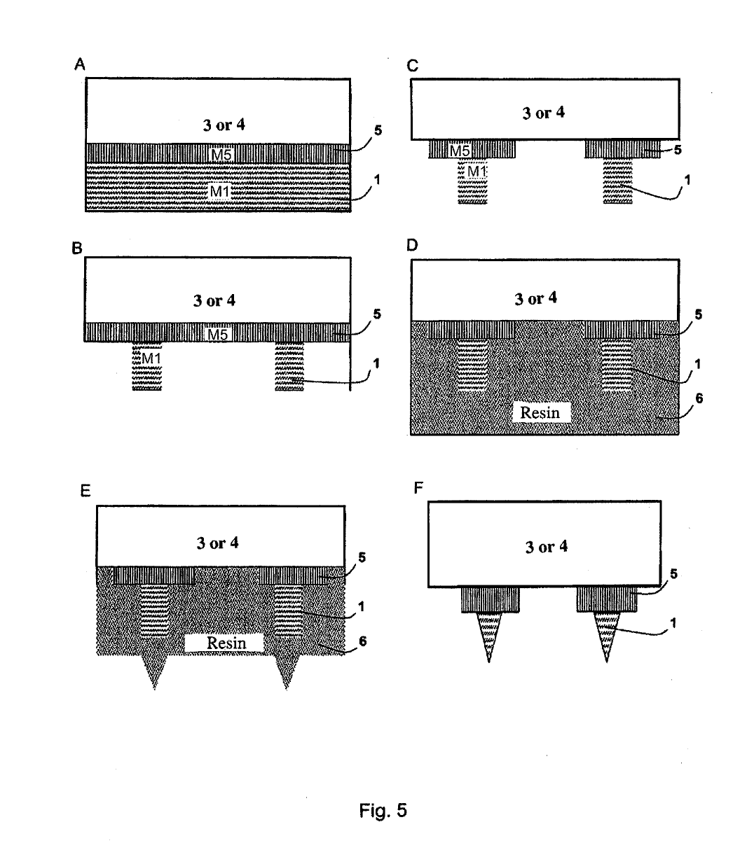

An inventive interconnect device may be made in the following way, shown in FIG. 5:
multi-layer deposition of the materials (M5 and M1, respectively) constituting the step 5 and the spike 1 on the chip 4 or the substrate 3 (FIG. 5A);
resin deposition/photo/engraving of the layer made of material M1 (FIG. 5B);
resin deposition/photo/engraving of the layer made of material M5 (FIG. 5C);
deposition of a “planarizing” resin 6 (FIG. 5D);
stage of resin impression moulding and resin reticulation at temperature (FIG. 5E), or with UV;
resin shape replication by ion milling or plasma RIE (FIG. 5F).

The document US 2005/191842 describes the making of a polyimide step, onto which it is conceivable to make inserts as described above.

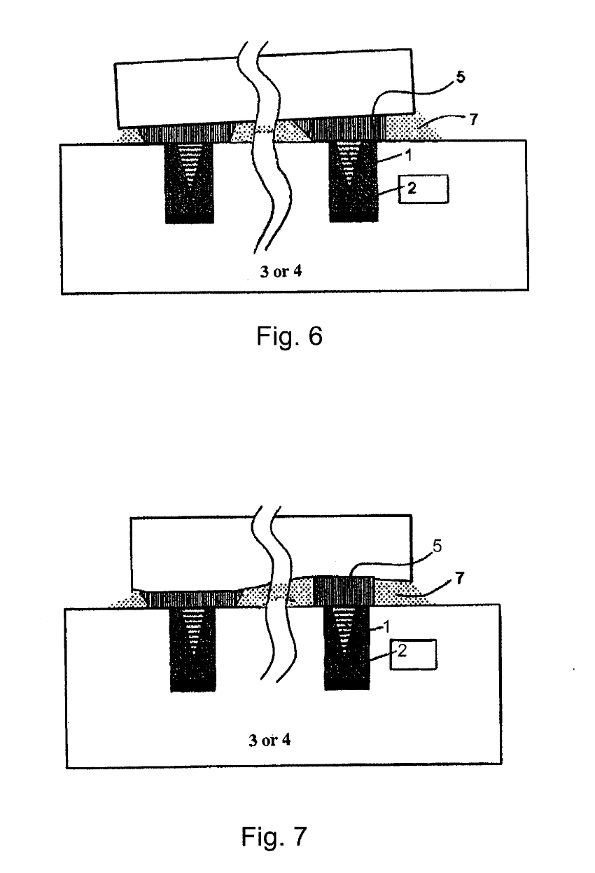

The insertion of the spike 1, mounted on a deformable block 5, into the ductile casing 2 of the corresponding element (chip 4 or substrate 3) and the retention of the interconnect by means of adhesive 7 are shown in FIGS. 6 and 7, in the case of parallelism defects and wafer-related flatness defects, respectively.

It is quite clear from the present application that an inventive assembly offers many advantages by making it possible to:
control the blocking of the z insertion by means of the step or stop block located underneath the insert;
increase the tolerance in respect of the insertion pressure through deformation of the block bringing about the homogenization of the pressure on the component;
compensate for the flatness defects of the surfaces by deformation of the block;
manage the surplus matter discharged during insertion avoiding the creation of short-circuits by the empty space between the spikes;
control the thickness between the chip and the substrate through the thickness of the step, thereby allowing the integration of a uniform adhesive film.

1. A method for electrical connection between:
a component comprising, on one face, a set of conductive inserts resting on conductive blocks positioned at the surface of the component; and
a second component comprising, on one face, a set of conductive buried regions, located opposite the inserts and having at least one dimension smaller than that of the blocks in their contact region,
comprising inserting the inserts into the buried regions, according to which:
the conductive block is made out of deformable material (M5), having greater ductility than that of the material (M1) constituting the insert and than that of the material (M2) constituting the region; and
the conductive block has a h′ defined by the following formula:
$${h}^{′} \geq \frac{tan ( α ) \cdot d}{Y / 100}$$
wherein:
α represents the parallelism defect;
d represents the maximum distance between two inserts; and
Y represents the deformation of the block supporting the insert.
or by the following formula:
$${h}^{′} \geq \frac{Y}{100} \cdot Δ h$$
wherein:
Δh represents the variation in maximum height between two interconnect elements; and
Y represents the deformation of the block supporting the insert.

2. The connection method as claimed in claim 1, wherein the insert is made out of gold (Au) and in that the block is composed of aluminium (Al) or indium (In), or is made out of polymer coated with a film of Au.

3. The connection method as claimed in claim 1, wherein the inserts are inserted into the regions until the blocks are stopped, at least locally.

4. The connection method as claimed in claim 1, wherein mechanical holding between the two components is provided by bonding at the interface of the two components.

5. The connection method as claimed in claim 4, wherein the volume of adhesive is determined in accordance with the following formula:
Vadhesive=1.1*(pitch²−L*l)*h′*N
where:
pitch denotes the repetitive pitch between two elementary patterns;
N denotes the number of interconnect elements;
h′ denotes the height of the blocks;
L denotes the width of the blocks;
l denotes the length of the blocks.
